(19) United States
(12) Patent Application Publication
(10) Pub. No.: US 2011/0237212 A1
(43) Pub. Date: Sep. 29, 2011

(54) RADIO RECEIVING CIRCUIT

(75) Inventor: Gaku Takemura, Kanagawa (JP)

(73) Assignee: KABUSHIKI KAISHA TOSHIBA, Tokyo (JP)

(21) Appl. No.: 13/022,954

(22) Filed: Feb. 8, 2011

(30) Foreign Application Priority Data
Mar. 24, 2010 (JP) 2010-068492

(51) Int. Cl. H03D 7/16

(52) U.S. Cl. 455/131

(57) ABSTRACT

According to one embodiment, a radio receiving circuit includes a low-noise amplifier, a frequency conversion circuit, a capacitor interposed between the low-noise amplifier and the frequency conversion circuit, and an operational amplifier that includes a feedback resistor and amplifies a baseband signal. The gains in the frequency conversion circuit and the operational amplifier are kept constant irrespective of the level of a local oscillation frequency input to the frequency conversion circuit.

### CROSS-REFERENCE TO RELATED APPLICATIONS

This application is based upon and claims the benefit of priority from the prior Japanese Patent Application No. 2010-068492, filed on Mar. 24, 2010; the entire contents of which are incorporated herein by reference.

### FIELD

Embodiments described herein relate generally to a radio receiving circuit.

### BACKGROUND

In recent years, according to the spread of mobile radio communication by a cellular phone and the like, various radios having higher performance have been devised. In particular, a direct conversion system is used for a radio receiver. The direct conversion system is also called directly converting system. The direct conversion system is a system for directly converting a high frequency (radio frequency; RF) into a low frequency (baseband frequency; BB frequency) not through an intermediate frequency (IF frequency). The radio receiver employing the direct conversion system mainly includes a low noise amplifier (LNA), a frequency converter (a mixer), and a low pass filter (LPF). The LNA is an amplifier that amplifiers the RF. The mixer frequency-converts the RF into the BB. The LPF removes unnecessary wave components of the BB.

Performance required of such a receiver is evaluated using indexes such as noise performance, distortion performance, gain, and power consumption. To optimally show these kinds of performance in the entire receiver, it is important to allocate the performance indexes to respective individual blocks of the receiver and correctly realize the performance indexes required in units of blocks. A table or a diagram for distributing the performance indexes of the entire receiver to the respective blocks or a concept of the distribution is called level diagram.

Among radio systems in recent years, some radio system has a wide range of RF frequencies allocated to the system. In such a radio system, when the gain in units of blocks is not constant, in some case, inconsistency occurs in the other level diagrams of the noise, the distortion, and the like and the performance of the radio system as a whole is deteriorated. Therefore, it is important not only to keep the gain of the entire radio system but also to keep the gain in a band in units of blocks because the performance other than the gain is also optimally realized in the entire receiver.

On the other hand, when a radio is manufactured by using a CMOS process, in a passive mixer employed for a mixer block, when a parameter such as the impedance of a block at a pre-stage of the mixer fluctuates, in some case, the fluctuation affects a circuit operation of a block at a post-stage of the mixer. Similarly, when a parameter such as the impedance of the block at the post-stage of the mixer fluctuates, in some case, the fluctuation affects a circuit operation of the block at the pre-stage of the mixer. Therefore, it is required to design the receiver including the passive mixer sufficiently taking into account an interaction between the blocks.

### BRIEF DESCRIPTION OF THE DRAWINGS

FIG. 1 is a block diagram of a schematic configuration of a radio receiving circuit according to a first embodiment of the present invention;

FIG. 2 is a diagram of an equivalent circuit of a baseband unit of the radio receiving circuit shown in FIG. 1;

FIG. 3 is a diagram for explaining the operation of a frequency conversion circuit shown in FIG. 1;

FIG. 4 is a diagram of an equivalent circuit of the frequency conversion circuit shown in FIG. 3;

FIG. 5 is a diagram of a circuit model for explaining the input and output impedance of the frequency conversion circuit of the radio receiving circuit shown in FIG. 1;

FIG. 6 is a diagram for explaining gains of units of the radio receiving circuit shown in FIG. 1;

FIGS. 7A and 7B are characteristic charts of a local oscillation frequency and the gain of a baseband unit;

FIG. 8 is a diagram of a schematic configuration of a radio receiving circuit according to a second embodiment of the present invention;

FIG. 9 is a diagram of an equivalent circuit of a baseband unit of the radio receiving circuit shown in FIG. 8;

FIG. 10 is a diagram of a schematic configuration of a radio receiving circuit according to a third embodiment of the present invention;

FIG. 11 is a diagram of an equivalent circuit of a baseband unit of the radio receiving circuit shown in FIG. 10;

FIG. 12 is a diagram of a schematic configuration of a radio receiving circuit according to a fourth embodiment of the present invention;

FIG. 13 is a diagram of an equivalent circuit of a baseband unit of the radio receiving circuit shown in FIG. 12;

FIG. 14 is a diagram of a schematic configuration of a radio receiving circuit according to a fifth embodiment of the present invention; and

FIG. 15 is a diagram of an equivalent circuit of a baseband unit of the radio receiving circuit shown in FIG. 14.

### DETAILED DESCRIPTION

In general, according to one embodiment, a radio receiving circuit includes a low-noise amplifier, a frequency conversion circuit, a capacitor interposed between the low-noise amplifier and the frequency conversion circuit, and an operational amplifier that includes a feedback resistor and amplifies a baseband signal. The gains in the frequency conversion circuit and the operational amplifier are kept constant irrespective of the level of a local oscillation frequency input to the frequency conversion circuit.

Exemplary embodiments of a radio receiving circuit will be explained below in detail with reference to the accompanying drawings. The present invention is not limited to the following embodiments.

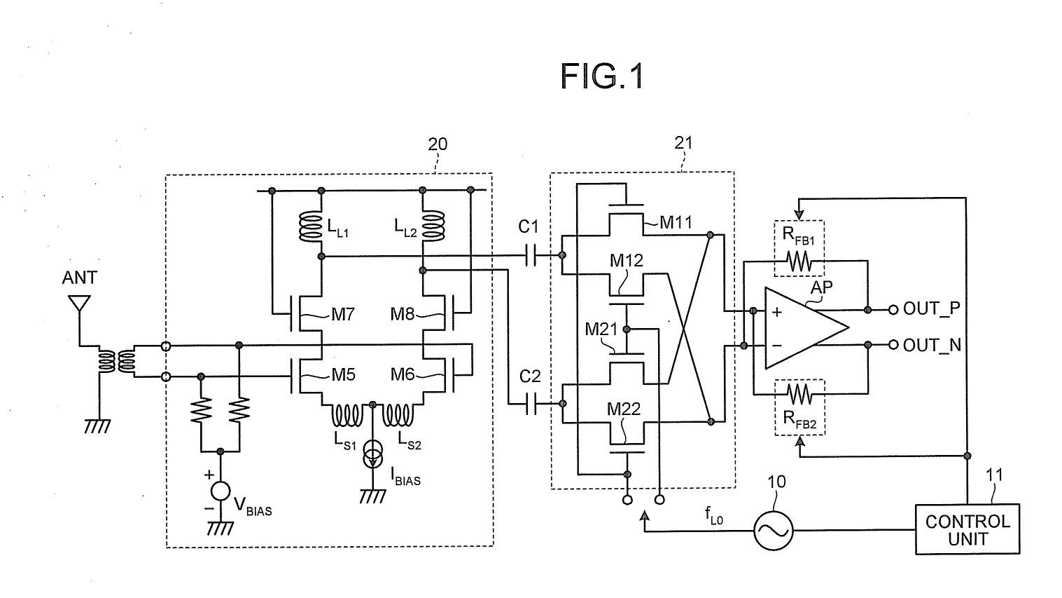

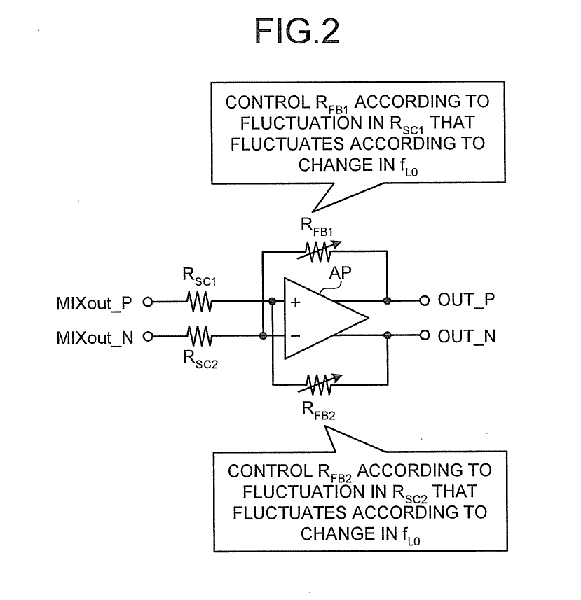

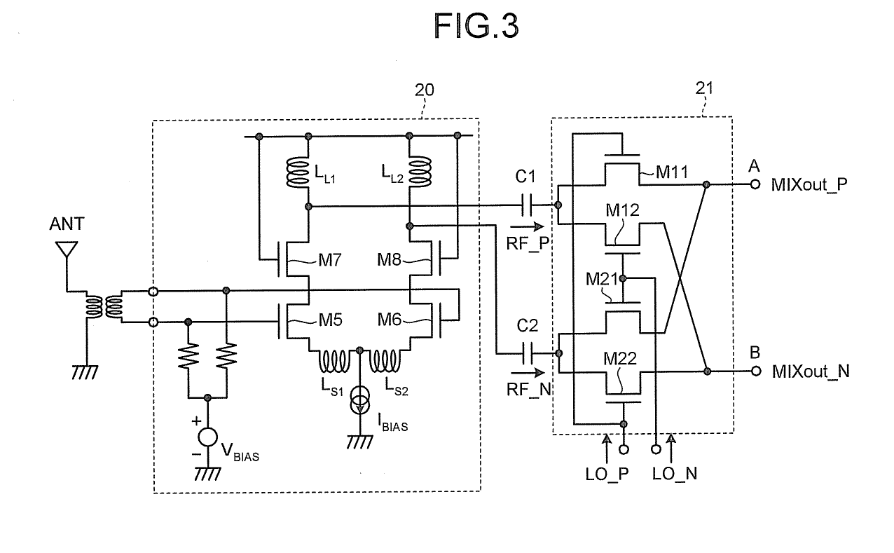

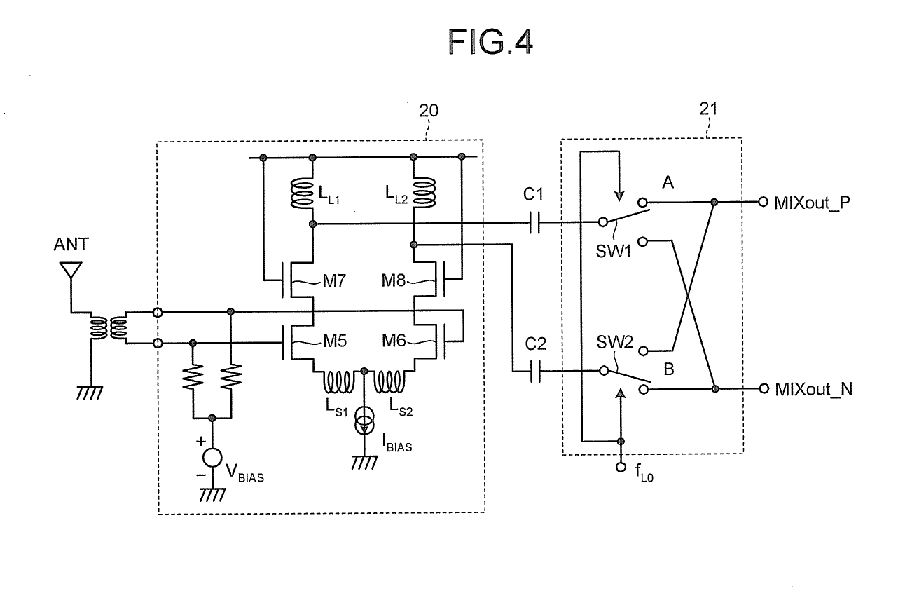

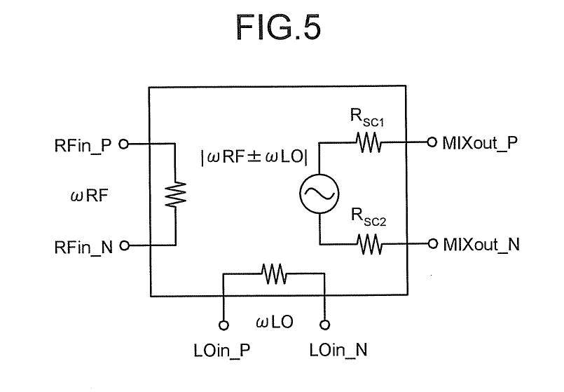

FIG. 1 is a block diagram of a schematic configuration of a radio receiving circuit according to a first embodiment of the present invention. FIG. 2 is a diagram of an equivalent circuit of a baseband unit of the radio receiving circuit shown in FIG. 1. Details of the baseband unit are explained later. FIG. 3 is a diagram for explaining the operation of the frequency conversion circuit shown in FIG. 1. FIG. 4 is a diagram of an equivalent circuit of the frequency conversion circuit shown in FIG. 3. FIG. 5 is a diagram of a circuit model for explaining the input and output impedance of the frequency conversion circuit of the radio receiving circuit shown in FIG. 1.

A low-noise amplifier (a first amplifier) 20, a frequency conversion circuit 21, an operational amplifier (a second amplifier) AP, a local signal source 10, and a control unit 11 included in the radio receiving circuit according to this embodiment are shown in FIG. 1. Capacitors C1 and C2 (first capacitors) for DC cut are connected between the low-noise amplifier 20 and the frequency conversion circuit 21.

The low-noise amplifier 20 includes, as main components, a transistor M7, a transistor M8, a transistor M5, and a transistor M6. As the transistors M5 to M6, for example, field effect transistors (MOSFETs) are used. A source of the transistor M7 and a drain of the transistor M5 are connected. A source of the transistor M8 and a drain of the transistor M6 are connected. A drain of the transistor M7 is connected to one end of an inductor L_{L1}. A drain of the transistor M8 is connector to one end of an inductor L_{L2}. A constant voltage source V_{DD} is applied to the other end of the inductor L_{L1} and a gate of the transistor M7. Similarly, the constant voltage source V_{DD} is applied to the other end of the inductor L_{L2} and a gate of the transistor M8. One end of an inductor L_{S1} is connected to a source of the transistor M5. One end of an inductor L_{S2} is connected to a source of the transistor M6. An electric current from a current source I_{BIAS} is supplied to a connection end of the other end of the inductor L_{S1} and the other end of the inductor L_{S2}.

The operation of the low-noise amplifier 20 is explained below. A radio frequency signal RF received by an antenna ANT is converted into a differential signal by a balun (balance to unbalance transformer and input to the low-noise amplifier 20. The transistors M5 and M6 of the low-noise amplifier 20 are biased by a bias voltage source V_{BIAS} and a bias resistor. Operating points of the transistors M5 and M6 are set by the bias voltage source V_{BIAS} and the bias resistor. A radio frequency signal RF (RFᵢₙ_{_{—}}P) is input to the gate of the transistor M6. A radio frequency signal RF (RFᵢₙ_{_{—}}N) is input to the gate of the transistor M5. Electric currents corresponding to the operation of the transistors M5 and M6 flow between the drains and the sources of the transistor M7 and M8. Therefore, voltage corresponding to the magnitude of the radio frequency signal RF is generated at connection ends of the transistors M7 and M8 and the inductors L_{L1} and L_{L2} that function as load resistors. This voltage is output to the capacitors C1 and C2.

The frequency conversion circuit 21 down-converts the radio frequency signal RF amplified by the low-noise amplifier 20 into a baseband signal. The frequency conversion circuit 21 includes a first differential transistor pair including a transistor M11 and a transistor M12 and a second differential transistor pair including a transistor M21 and a transistor M22. Sources of the transistors M11 and M12 are connected to each other. Sources of the transistors M21 and M22 are connected to each other. Drains of the transistors M11 and M21 are connected to each other. Drains of the transistors M12 and M22 are connected to each other. Gates of the transistors M12 and M21 are connected to each other. Gates of the transistors M11 and M22 are connected to each other. As the transistors M11, M12, M21, and M22, for example, field effect transistors (MOSFETs) are used.

One end of the first differential transistor pair is connected to one end of the capacitor C1. One end of the second differential transistor pair is connected to one end of the capacitor C2. The other end of the capacitor C1 is connected to a connection end of the inductor L_{L1} and the transistor M7 included in the low-noise amplifier 20. The other end of the capacitor C2 is connected to a connection end of the inductor L_{L2} and the transistor M7.

An inverting input terminal and a noninverting input terminal are provided in the operational amplifier AP. The drain of the transistor M11 and the drain of the transistor M21 are connected to the noninverting input terminal of the operational amplifier AP. The drain of the transistor M12 and the drain of the transistor M22 are connected to the inverting input terminal of the operational amplifier AP. One output terminal of the operational amplifier AP is connected to the inverting input terminal via a feedback resistor R_{FB1}. The other output terminal of the operational amplifier AP is connected to the noninverting input terminal via a feedback resistor R_{FB2}. The operational amplifier AP configured in this way functions as a baseband amplifier.

The control unit 11 controls the local signal source 10 and changes the resistance of the feedback resistors R_{FB1} and R_{FB2}. A frequency of a local oscillation signal output from the local signal source 10 (hereinafter simply referred to as “local oscillation frequency”) f_{L0} is input to the frequency conversion circuit 21.

The baseband unit is a circuit including the frequency conversion circuit 21, the operational amplifier AP, and the feedback resistors R_{FB1} and R_{FB2}.

An equivalent circuit of the baseband unit is explained with reference to FIG. 2. First, mixer output impedances R_{SC1} and R_{SC2} are output impedances of the frequency conversion circuit 21. In FIG. 2, the mixer output impedance R_{SC1} is input to the noninverting input terminal (a terminal indicated by +) of the operational amplifier AP. The mixer output impedance R_{SC2} is input to the inverting input terminal (a terminal indicated by −) of the operational amplifier AP. In the following explanation, in this application, the mixer output impedances R_{SC1} and R_{SC2} are generally referred to as mixer output impedance R_{SC}.

The mixer output impedance R_{SC} is generated by a switched capacitor. The switched capacitor depends on the capacitance of the capacitors C1 and C2 and a value of the local oscillation frequency f_{L0} input to the frequency conversion circuit 21. In this way, the mixer output impedance R_{SC} fluctuates according to changes in the local oscillation frequency f_{L0} and the capacitance of the capacitors C1 and C2. Therefore, in the radio receiving circuit according to this embodiment, the resistance of the feedback resistor R_{FB} is changed according to fluctuation in the mixer output impedance R_{SC}. For example, the resistance of the feedback resistors R_{FB1} and R_{FB2} is controlled to decrease as the local oscillation frequency f_{L0} rises. The resistance of the feedback resistors R_{FB1} and R_{FB2} is controlled to increase as the local oscillation frequency f_{L0} falls. As a result, the gain of the operational amplifier AP obtained by R_{FB}/R_{SC} is kept constant.

In the following explanation, the influence of fluctuation in the mixer output impedance R_{SC} on the gain of the baseband unit is explained in association with the operation of the frequency converting circuit 21.

First, the operation of the frequency conversion circuit 21 is specifically explained with reference to FIG. 3. A local oscillation signal LO_P from the local signal source 10 is input to the gates of the transistors M11 and M22. A local oscillation signal LO_N is input to the gates of the transistors M12 and M21. The transistors M21 to M22 are controlled to be turned on and off by the local oscillation signals LO_P and LO_N. A radio frequency signal RF_P input to the first differential transistor pair is multiplied with the local oscillation signal LO_P. A radio frequency signal RF_N input to the second differential transistor pair is multiplied with the local oscillation signal LO_N. As a result, the radio frequency signal RF_P is converted into a baseband signal MIXout_P. The radio frequency signal RF_N is converted into a baseband signal MIXout_N. The baseband signals MIXout_P and MIXout_N are input to the operational amplifier AP as differential signals.

The principle of the switched capacitor is explained with reference to FIG. 4. The first differential transistor pair can be regarded as a switch SW1 that is switched at the timing of the local oscillation frequency f_{L0}. The second differential transistor pair can be regarded as a switch SW2 that is switched at the timing of the local oscillation frequency f_{L0}. Therefore, when the impedance of the inductors L_{L1} and L_{L2} is sufficiently small compared with the impedance of the capacitors C1 and C2, it looks as if the switched capacitor is present between output ends Out_P and Out_N of the frequency conversion circuit 21.

A relation among the mixer output impedance R_{SC}, the capacitors, and the switches is specifically explained below. Mixer output impedance derived from the capacitor C1 and the switch SW1 is represented as 1/(C1*f_{L0}) according to the principle of the switched capacitor. Mixer output impedance derived from the capacitor C2 and the switch SW2 is represented as 1/(C2*f_{L0}) according to the principle of the switched capacitor.

Therefore, when C=C1=C2 is set, the impedance R_{SC} between the output ends Out_P and Out_N of the frequency conversion circuit 21 is represented as 1/(2*f_{L0}*C)

As explained above, the mixer output impedance R_{SC} is a value that depends on the capacitance of the capacitors C1 and C2 and a value of the local oscillation frequency f_{L0}. For example, when the capacitance of the capacitors C1 and C2 is set to 1 picofarad and the local oscillation frequency f_{L0} is set to 1 gigahertz, the mixer output impedance R_{SC} of the frequency conversion circuit 21 is 500 ohms. When the capacitance of the capacitors C1 and C2 is set to 1 picofarad and the local oscillation frequency f_{L0} is set to 5 gigahertz, the output impedance R_{SC} is 100 ohms. In this way, when the local oscillation frequency f_{L0} is equal to lower than 5 gigahertz or the capacitance of the capacitors C1 and C2 is, for example, about 1 picofarad to 5 picofarad, a value of the mixer output impedance R_{SC} of the frequency conversion circuit 21 is a large value compared with ON resistance and wiring parasitic resistance of a switch of a mixer. Therefore, the mixer output impedance R_{SC} affects the gain of the operational amplifier AP.

In other words, when the mixer output impedance R_{SC} fluctuates according to a change in the capacitance of the capacitors C1 and C2 or the local oscillation frequency f_{L0}, the gain of the baseband unit (equivalent to the operational amplifier AP) fluctuates. In a radio system having a wide working frequency range, it is likely that in-band gain deviation poses a problem. As a cause of the in-band gain deviation, fluctuation in the mixer output impedance R_{SC} due to a switched capacitor operation of the mixer is conceivable. If the gain fluctuation in the baseband unit can be suppressed, it is possible to make the level diagrams of the noise and the gain appropriate and improve the performance of the entire system (the RF unit to the BB unit).

The input and output impedance in the frequency conversion circuit 21 is explained with reference to FIG. 5. In the circuit model shown in FIG. 5, the resistance between the radio frequency signals RFᵢₙ_{_{—}}P and RFᵢₙ_{_{—}}N is the input impedance of the input of the radio frequency signal RF. The resistance between local oscillation signals LOin_P and LOin_N is the input impedance of the input of the local oscillation signal L0. The resistance between MIXout_P and MIX_out_N indicates the mixer output impedances R_{SC1} and R_{SC2}.

Input ends (one ends) of the mixer output impedances R_{SC1} and R_{SC2} are connected to an imaginary internal voltage source that generates a frequency after frequency conversion. In the circuit model shown in FIG. 5, the input and the output are isolated.

The operation of the radio receiving circuit according to this embodiment is explained below in association with the circuit model shown in FIG. 5. When the transistor M5 is turned on and the transistor M6 is turned off by the radio frequency signals RF_{IN}_{_{—}}P and RF_{IN}_{_{—}}N received by the antenna ANT, voltage corresponding to the magnitude of the radio frequency signal RF is generated at the connection end of the inductor L_{L2} and the transistor M8. When the transistor M5 is turned off and the transistor M6 is turned on by the radio frequency signals RF_{IN}_{_{—}}P and RF_{IN}_{_{—}}N received by the antenna ANT, voltage corresponding to the magnitude of the radio frequency signal RF is generated at the connection end of the inductor L_{L1} and the transistor M7.

Voltage having a frequency obtained by adding the frequency of the local oscillation signals LOin_P and LOin_N (ωLO) to or subtracting the frequency from the frequency of the radio frequency signals RF_P and RF_N (ωRF) is applied to one ends of the mixer output impedances R_{SC1} and R_{SC2} shown in FIG. 5. Baseband signals MIXout_P and MIXout_N corresponding to a value of the mixer output impedances R_{SC1} and R_{SC2} are generated at the other ends of the mixer output impedances R_{SC1} and R_{SC2}. The mixer output impedances R_{SC1} and R_{SC2} decrease as the local oscillation frequency f_{L0} rises and increase as the local oscillation frequency f_{L0} falls. The gain (amplification ratio) of the operation amplifier AP shown in FIG. 2 that receives the baseband signals MIXout_P and MIXout_N as an input is calculated by R_{FB}/R_{SC}. When the resistance of the feedback resistor R_{FB} is constant, the gain increases as the local oscillation frequency f_{L0} rises and decreases as the local oscillation frequency f_{L0} falls. Therefore, to keep the gain of the operational amplifier AP constant, it is necessary to control the resistance of the feedback resistor R_{FB} to increase as the mixer output impedance R_{SC} increases and control the resistance of the feedback resistor R_{FB} to decrease as the mixer output impedance R_{SC} decreases. The radio receiving circuit according to this embodiment is configured to change the resistance of the feedback resistor R_{FB} according to the magnitude of the local oscillation frequency f_{L0}. Therefore, it is possible to keep the gain of the operational amplifier AP constant.

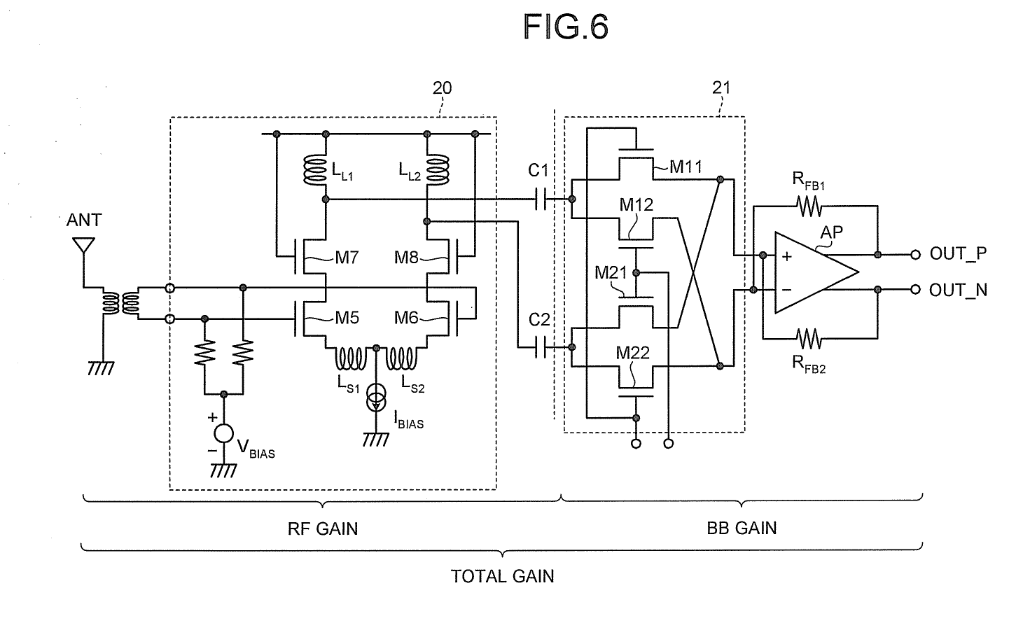

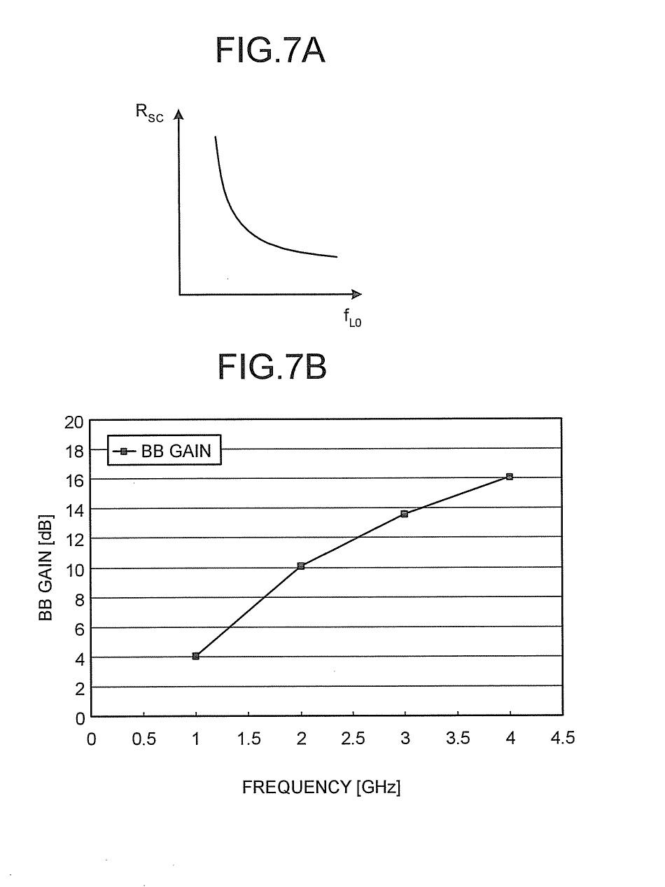

A relation between the output impedance R_{SC} and the resistance of the feedback resistor R_{FB} as variable resistance is specifically explained below with reference to FIGS. 6 and 7.

FIG. 6 is a diagram for explaining the gains of the units of the radio receiving circuit shown in FIG. 1. FIGS. 7A and 7B are characteristic charts of the local oscillation frequency f_{L0} and the gain of the baseband unit.

In FIG. 6, a gain from a radio frequency signal RF input end of the low-noise amplifier 20 to the connection ends of the capacitors C1 and C2 and the frequency conversion circuit 21 is defined as “RF gain”. A gain from the connection ends of the capacitors C1 and C2 and the frequency conversion circuit 21 to the output end of the operational amplifier AP is defined as “BB gain”. A gain obtained by adding up the “RF gain” and the “BB gain” is defined as “total gain”. Because the frequency conversion circuit 21 is a passive mixer, the gain thereof is “1”. Therefore, in the “BB gain”, the gain of the operational amplifier AP is predominant.

A state in which the mixer output impedance R_{SC} changes depending on the local oscillation frequency f_{L0} is shown in FIG. 7A. For example, it is seen that the output impedance R_{SC} of the frequency conversion circuit 21 decreases as the local oscillation frequency f_{L0} rises. A state in which the BB gain changes depending on the local oscillation frequency f_{L0} is shown in FIG. 7B. For example, it is seen that the BB gain increases as the local oscillation frequency f_{L0} rises.

The gain of the operational amplifier AP increases in this way because a gain calculated by feedback resistance/input resistance increases as the output impedance R_{SC} equivalent to the input resistance of the operational amplifier AP decreases.

Therefore, the increase in the gain can be suppressed if the feedback resistance is reduced as the input resistance decreases. In the radio receiving circuit according to this embodiment, because the resistance of the feedback resistors R_{FB1} and R_{FB2} is controlled to decrease as the local oscillation frequency f_{L0} rises, the gain of the operational amplifier AP can be kept constant.

Usually, an increase in the “BB gain” results in deterioration in a noise figure (NF). As a specific example, when an amplification ratio (an exact numeric value that is not dB) in the low-noise amplifier 20 is set to “10”, an amplification ratio (an exact numeric value) in the frequency conversion circuit 21 is set to “1”, and an amplification ratio (an exact numeric value) in the operation amplifier AP is set to “1”, the “total gain” is “10”. Total output noise is a value obtained by multiplying a total value of noise N1 caused in the low-noise amplifier 20 and noise N2 caused in the frequency conversion circuit 21 with the amplification ratio “1” of the operational amplifier AP and adding up a result of the multiplication and noise N3 caused in the operational amplifier AP. In other words, the total output noise is N1+N2+N3.

On the other hand, when an amplification ratio (an exact numeric value that is not dB) in the low-noise amplifier 20 is set to “1”, an amplification ratio (an exact numeric value) in the frequency conversion circuit 21 is set to “1”, and an amplification ratio (an exact numeric value) in the operation amplifier AP is set to “10”, the “total gain” is also “10”. Total output noise is a value obtained by multiplying a total value of the noise N1 caused in the low-noise amplifier 20 and the noise N2 caused in the frequency conversion circuit 21 with the amplification ratio “10” of the operational amplifier AP and adding up a result of the multiplication and the noise N3 caused in the operational amplifier AP. In other words, the total output noise is 10*(N1+N2)+N3.

Even if the former “total gain” and the latter “total gain” are the same, the latter output noise is a value larger than the former output noise and, therefore, the latter noise figure NF is a larger value. In other words, the increase in the “BB gain” deteriorates the noise figure NF. Therefore, in the system having a wide working frequency range, to prevent the deterioration in the noise figure NF, it is important to make the “BB gain” constant.

The mixer output impedance R_{SC} of the radio receiving circuit according to this embodiment is calculated by the following formula:

R_{SC}=1/(2*C*f_{L0})

Therefore, R_{SC1} and R_{SC2} in FIG. 2 are calculated by the following formula:

R_{SC1}=R_{SC2}=R_{SC}/2=1/(4*C*f_{L0})

The BB gain of the radio receiving circuit is calculated by the following formula:

BB gain=R_{FB}/R_{SC1}=R_{FB}/R_{SC2}=4C*R_{FB}*f_{L0}

If the resistance of the feedback resistor R_{FB} is changed according to fluctuation in the mixer output impedance R_{SC}, which fluctuates according to a change in the local oscillation frequency f_{L0}, it is possible to keep the BB gain constant. The control unit 11 shown in FIG. 1 controls the resistance of the feedback resistors R_{FB1} and R_{FB2} to decrease, for example, as the local oscillation frequency f_{L0} rises. Therefore, the BB gain is kept constant with respect to the fluctuation in the local oscillation frequency f_{L0}.

As explained above, the radio receiving circuit according to this embodiment includes the low-noise amplifier 20 that amplifies a received radio frequency signal, the frequency conversion circuit 21 that multiplies together a signal from the low-noise amplifier 20 and a local oscillation signal and converts the multiplied signal into a baseband signal, the capacitors C1 and C2 interposed between the low-noise amplifier 20 and the frequency conversion circuit 21, and the operation amplifier AP that includes the feedback resistors R_{FB1} and R_{FB2} configured to be capable of changing a resistance value and amplifies the baseband signal. Therefore, it is possible to change, according to a change in the local oscillation frequency f_{L0}, the resistance of the feedback resistors R_{FB1} and R_{FB2} to make the “BB gain” constant. As a result, it is possible to suppress deterioration in the noise figure NF in the system having a wide working frequency range, the level diagrams are made appropriate, and it is possible to improve the performance of the entire system. In the radio receiving circuit according to this embodiment, because the resistance of the feedback resistors R_{FB1} and R_{FB2} are controlled to decrease as the local oscillation frequency f_{L0} rises, it is possible to keep the gain of the operational amplifier AP, i.e., the “BB gain” constant. Therefore, the noise figure NF is not deteriorated in the system having a wide working frequency range.

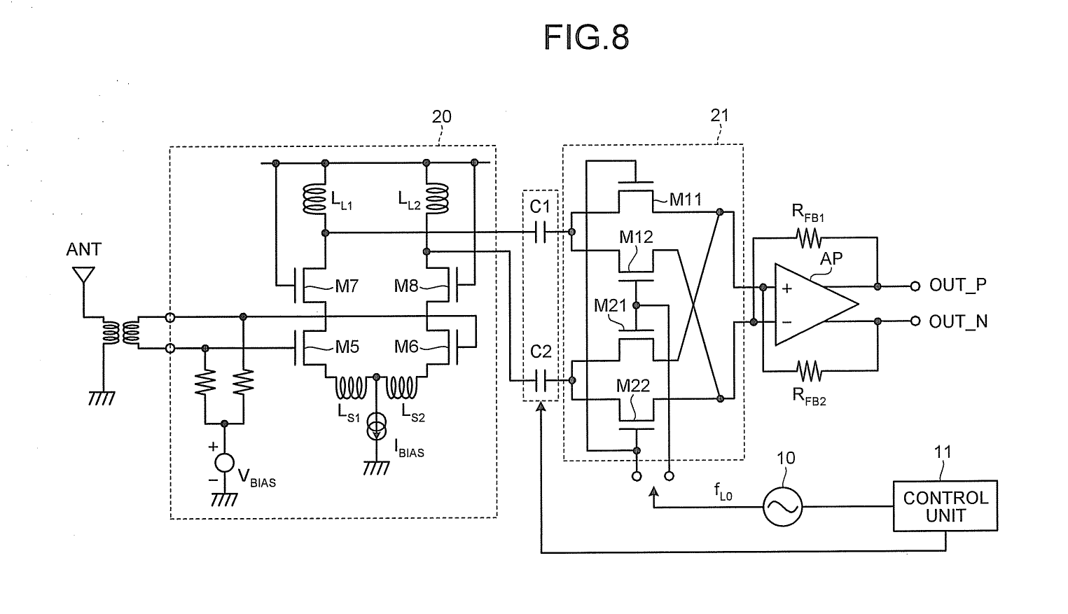

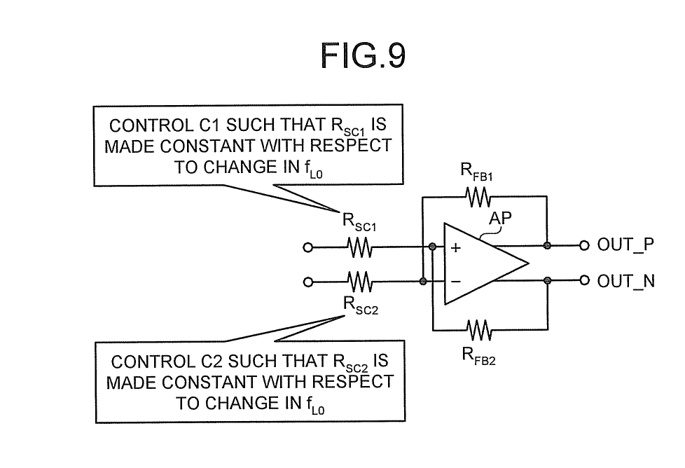

FIG. 8 is a diagram of a schematic configuration of a radio receiving circuit according to a second embodiment of the present invention. FIG. 9 is a diagram of an equivalent circuit of a baseband unit of the radio receiving circuit shown in FIG. 8. The radio receiving circuit according to this embodiment is different from the radio receiving circuit according to the first embodiment in that the capacitance of the capacitors C1 and C2 changes according to a control signal from the control unit 11. Components same as those in the first embodiment are denoted by the same reference numerals and signs and explanation of the components is omitted. Only differences are explained below.

The mixer output impedance R_{SC} of the radio receiving circuit according to this embodiment is calculated by the following formula:

R_{SC}=1/(2*C*f_{L0})

Therefore, R_{SC1} and R_{SC2} in FIG. 9 are calculated by the following formula:

R_{SC1}=R_{SC2}=R_{SC}/2=1/(4*C*f_{L0})

The BB gain of the radio receiving circuit is calculated by the following formula:

BB gain=R_{FB}/R_{SC1}=R_{FB}/R_{SC2}=4C*R_{FB}*f_{L0}

If the capacitance of the capacitors C1 and C2 is changed to make a value obtained by C*f_{L0} constant with respect to a change in the local oscillation frequency f_{L0}, it is possible to keep the mixer output impedance R_{SC} constant. Generalized formulation of gain deviation of the “RF gain” is often difficult. However, qualitatively, if the value obtained by C*f_{L0} is constant, fluctuation not only in the “BB gain” but also in the “RF gain” is reduced. The control unit 11 shown in FIG. 9 controls the capacitance of the capacitors C1 and C2 to decrease as the local oscillation frequency f_{L0} rises. Therefore, the BB gain is kept constant with respect to a change in the local oscillation frequency f_{L0}. Further, fluctuation in the “RF gain” is also reduced.

As explained above, the radio receiving circuit according to this embodiment includes the low-noise amplifier 20 that amplifies a received radio frequency signal, the frequency conversion circuit 21 that multiplies together a signal from the low-noise amplifier 20 and a local oscillation signal and converts the multiplied signal into a baseband signal, the capacitors C1 and C2 interposed between the low-noise amplifier 20 and the frequency conversion circuit 21 and configured to be capable of changing capacitance, and the operational amplifier AP that amplifies the baseband signal. Therefore, it is possible to make the “BB gain” constant and reduce fluctuation in the “RF gain”. As a result, compared with the radio receiving circuit according to the first embodiment, it is possible to further suppress deterioration in the noise figure NF and realize further appropriateness of the level diagrams.

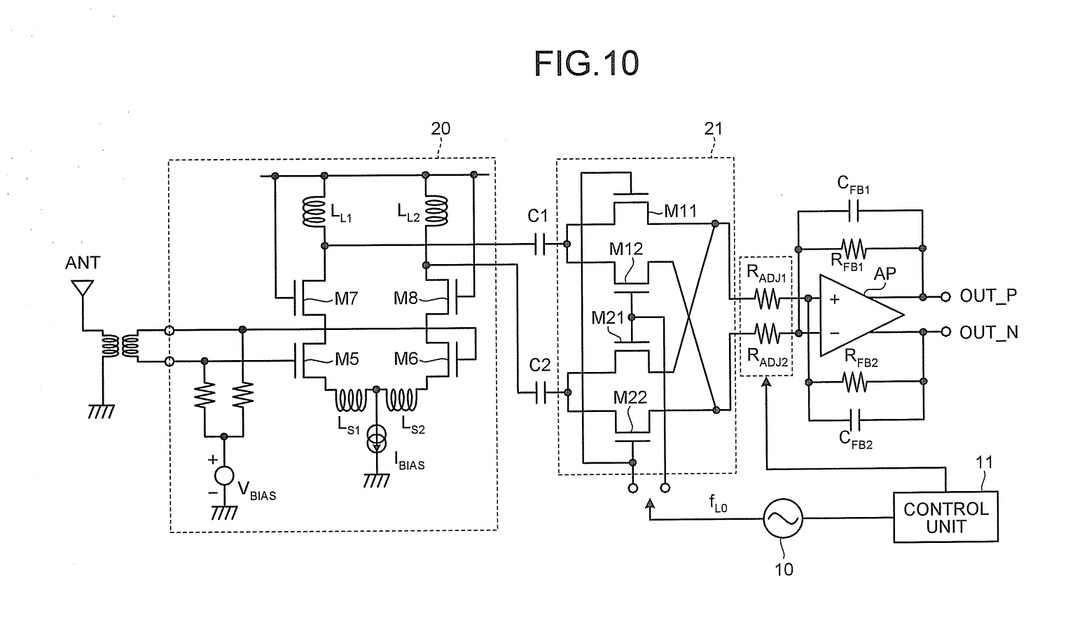

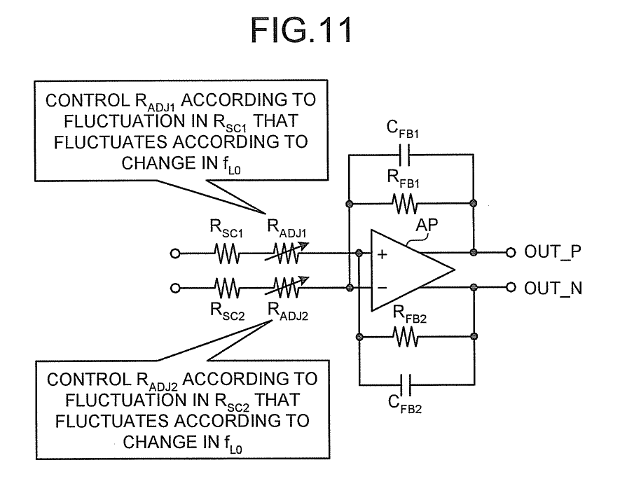

FIG. 10 is a diagram of a schematic configuration of a radio receiving circuit according to a third embodiment of the present invention. FIG. 11 is a diagram of an equivalent circuit of a baseband unit of the radio receiving circuit shown in FIG. 10. Components same as those in the first and second embodiments are denoted by the same reference numerals and signs and explanation of the components is omitted. Only differences are explained below.

A capacitor C_{FB1} is connected in parallel to the feedback resistor R_{FB1} of the operational amplifier AP. A capacitor C_{FB2} is connected in parallel to the feedback resistor R_{FB2}.

One end of an input adjusting resistor R_{ADJ1} is connected to the noninverting input terminal of the operational amplifier AP. One end of the input adjusting resistor R_{ADJ2} is connected to the inverting input terminal of the operational amplifier AP. The other end of the input adjusting resistor R_{ADJ1} is connected to the connection end of the transistor M11 and the transistor M21. The other end of the input adjusting resistor R_{ADJ2} is connected to the connection end of the transistor M12 and the transistor M22. The input adjusting resistors R_{ADJ1} and R_{ADJ2} adjust the input impedance of the operational amplifier AP.

After being amplified by the operational amplifier AP, a signal from the frequency conversion circuit 21 is output as an output signal. Because the capacitor C_{FB1} is connected in parallel to the feedback resistor R_{FB1} and the capacitor C_{FB2} is connected in parallel to the feedback resistor R_{FB2}, the operational amplifier AP functions as a low-pass filter.

The mixer output impedance R_{SC} of the radio receiving circuit according to this embodiment is calculated by the following formula:

R_{SC}=1/(2*C*f_{L0})

Therefore, R_{SC1} and R_{SC2} in FIG. 11 are calculated by the following formula:

R_{SC1}=R_{SC2}=R_{SC}/2=1/(4*C*f_{L0})

The BB gain of the radio receiving circuit is calculated by the following formula at a frequency sufficiently smaller than an LPF cut-off frequency by the operational amplifier AP:

BB gain=R_{FB}/(R_{SC1}+RADJ)=R_{FB}/(R_{SC2}+RADJ)=R_{FB}/(1/(4*C*f_{L0})+RADJ)

If the resistance of the input adjusting resistors R_{ADJ1} and R_{ADJ2} is changed according to fluctuation in the mixer output impedance R_{SC} that fluctuates according to a change in the local oscillation frequency f_{L0}, it is possible to keep the BB gain constant. The control unit 11 shown in FIG. 10 controls the resistance of the input adjusting resistors R_{ADJ1} and R_{ADJ2} to increase as the local oscillation frequency f_{L0} rises. Therefore, the BB gain is kept constant with respect to a change in the local oscillation frequency f_{L0}.

As explained above, the radio receiving circuit according to this embodiment includes the low-noise amplifier 20 that amplifies a received radio frequency signal, the frequency conversion circuit 21 that multiplies together a signal from the low-noise amplifier 20 and a local oscillation signal and converts the multiplied signal into a baseband signal, the capacitors C1 and C2 interposed between the low-noise amplifier 20 and the frequency conversion circuit 21, the operation amplifier AP that amplifies the baseband signal, and the input adjusting resistors R_{ADJ1} and R_{ADJ2} interposed between the frequency conversion circuit 21 and the operational amplifier AP and configured to be capable of changing resistance. Therefore, it is possible to keep the “BB gain” constant. As a result, it is possible to make the level diagrams appropriate while having a function of a low-pass filter.

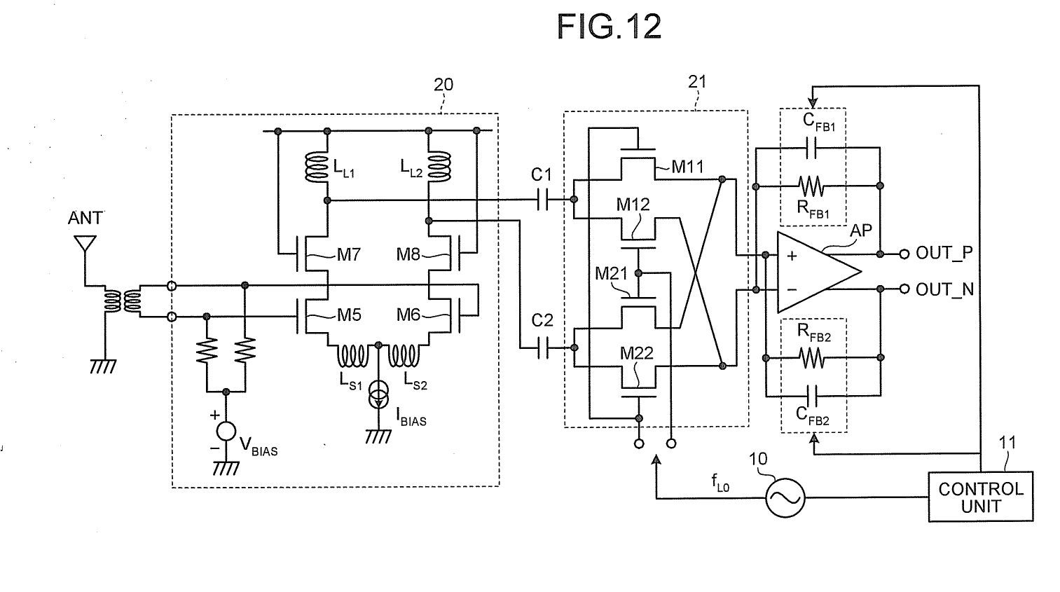

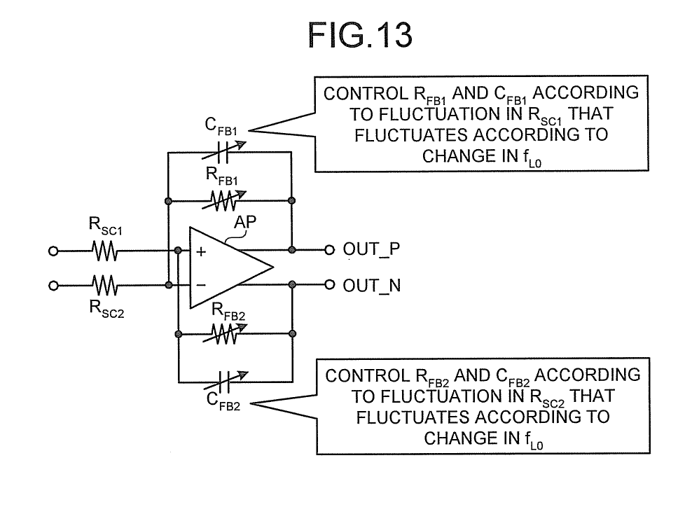

FIG. 12 is a diagram of a schematic configuration of a radio receiving circuit according to a fourth embodiment of the present invention. FIG. 13 is a diagram of an equivalent circuit of a baseband unit of the radio receiving circuit shown in FIG. 12. The radio receiving circuit according to this embodiment is different from the radio receiving circuit according to the third embodiment in that the input adjusting resistors R_{ADJ1} and R_{ADJ2} are removed and the capacitance of the capacitors C_{FB1} and C_{FB2} (second capacitors) and the resistance of the feedback resistors R_{FB1} and R_{FB2} change according to a control signal from the control unit 11. Components same as those in the first to third embodiments are denoted by the same reference numerals and signs and explanation of the components is omitted. Only differences are explained below.

The mixer output impedance R_{SC} of the radio receiving circuit according to this embodiment is calculated by the following formula:

R_{SC}=1/(2*C*f_{L0})

Therefore, R_{SC1} and R_{SC2} in FIG. 13 are calculated by the following formula:

R_{SC1}=R_{SC2}=R_{SC}/2=1/(4*C*f_{L0})

The BB gain of the radio receiving circuit is calculated by the following formula at a frequency sufficiently smaller than an LPF cut-off frequency by the operational amplifier AP:

BB gain=R_{FB}/R_{SC1}=R_{FB}/R_{SC2}=4C*R_{FB}*f_{L0}

An LPF cut-off frequency fc by the operational amplifier AP is calculated by the following formula:

fc=1/(2π*R_{FB}*C_{FB})

If the resistance of the feedback resistors R_{FB1} and R_{FB2} is changed according to fluctuation in the mixer output impedance R_{SC} that fluctuates according to a change in the local oscillation frequency f_{L0}, it is possible to keep the BB gain constant. However, because the change in the resistance of the feedback resistors R_{FB1} and R_{FB2} affects the LPF cut-off frequency fc, it is necessary to also change the capacitance of the capacitors C_{FB1} and C_{FB2} according to the change in the resistance of the feedback resistors R_{FB1} and R_{FB2}. In other words, a time constant of the feedback resistors R_{FB1} and R_{FB2} and the capacitors C_{FB1} and C_{FB2} is constant. The control unit 11 shown in FIG. 12 controls the resistance of the feedback resistors R_{FB1} and R_{FB2} to decrease, for example, as the local oscillation frequency f_{L0} rises. Further, the control unit 11 increases the capacitance of the capacitors C_{FB1} and C_{FB2} to make the LPF cut-off frequency fc constant as the resistance of the feedback resistors R_{FB1} and R_{FB2} decreases. Therefore, the BB gain is kept constant and the LPF cut-off frequency fc is kept constant with respect to a change in the local oscillation frequency f_{L0}.

As explained above, the radio receiving circuit according to this embodiment includes the low-noise amplifier 20 that amplifies a received radio frequency signal, the frequency conversion circuit 21 that multiplies together a signal from the low-noise amplifier 20 and a local oscillation signal and converts the multiplied signal into a baseband signal, the capacitors C1 and C2 interposed between the low-noise amplifier 20 and the frequency conversion circuit 21, and the operation amplifier AP that includes the feedback resistors R_{FB1} and R_{FB2} configured to be capable of changing resistance and the capacitors C_{FB1} and C_{FB2} configured to be capable of changing capacitance and amplifies the baseband signal. Therefore, it is possible to keep the “BB gain” constant and make a time constant for determining a cut-off frequency of a low-pass filter constant. As a result, it is possible to suppress deterioration in the noise figure NF in a system having a wide working frequency range.

In the radio receiving circuit according to this embodiment, because resistors such as the input adjusting resistors R_{ADJ1} and R_{ADJ2} are not used in the baseband unit, an increase in thermal noise due to the resistance of the resistors does not occur. Therefore, it is possible to reduce the noise figure NF compared with the radio receiving circuit according to the third embodiment. As a result, the level diagrams are properly maintained and it is possible to further improve the performance of the entire system.

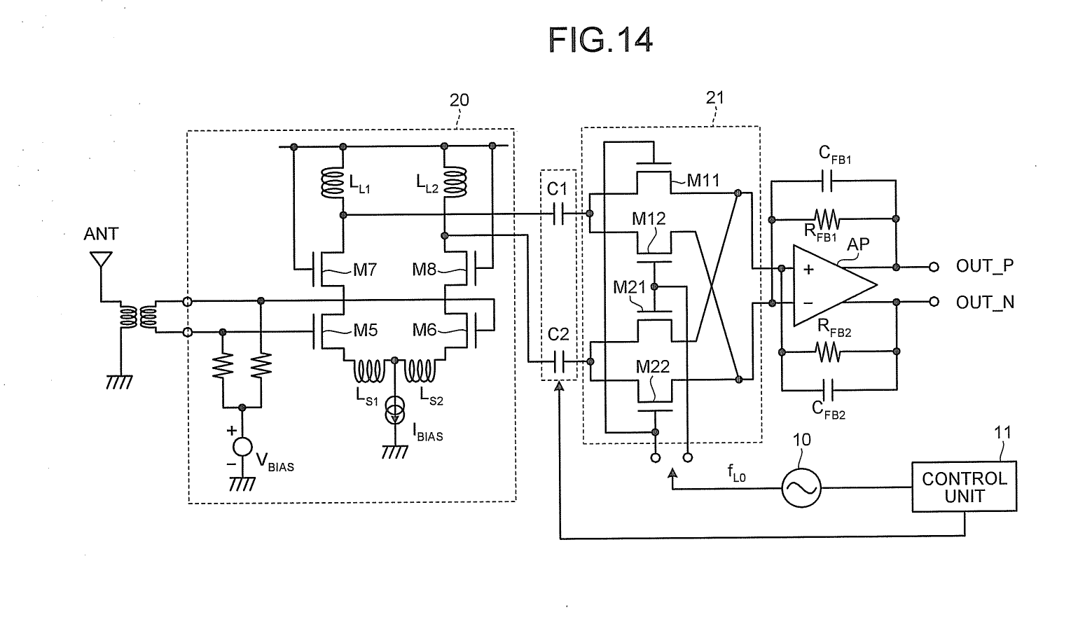

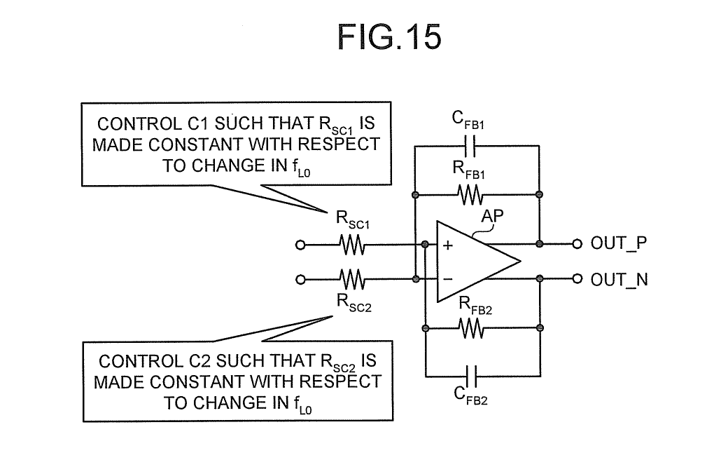

FIG. 14 is a diagram of a schematic configuration of a radio receiving circuit according to a fifth embodiment of the present invention. FIG. 15 is a diagram of an equivalent circuit of a baseband circuit of the radio receiving circuit shown in FIG. 14. The radio receiving circuit according to this embodiment is different from the radio receiving circuit according to the fourth embodiment in that the capacitance of the capacitors C1 and C2 changes according to a control signal from the control unit 11. Components same as those in the first to fourth embodiments are denoted by the same reference numerals and signs and explanation of the components is omitted. Only differences are explained below.

The mixer output impedance R_{SC} of the radio receiving circuit according to this embodiment is calculated by the following formula:

R_{SC}=1/(2*C*f_{L0})

Therefore, R_{SC1} and R_{SC2} in FIG. 15 are calculated by the following formula:

R_{SC1}=R_{SC2}=R_{SC}/2=1/(4*C*f_{L0})

The BB gain of the radio receiving circuit is calculated by the following formula at a frequency sufficiently smaller than an LPF cut-off frequency by the operational amplifier AP:

BB gain=R_{FB}/R_{SC1}=R_{FB}/R_{SC2}=4C*R_{FB}*f_{L0}

If the capacitance of the capacitors C1 and C2 is changed to make a value obtained by C*f_{L0} constant with respect to a change in the local oscillation frequency f_{L0}, it is possible to keep the mixer output impedance R_{SC} constant. Generalized formulation of gain deviation of the “RF gain” is often difficult. However, qualitatively, if the value obtained by C*f_{L0} is constant, fluctuation not only in the “BB gain” but also in the “RF gain” is reduced. The control unit 11 shown in FIG. 14 controls the capacitance of the capacitors C1 and C2 to decrease as the local oscillation frequency f_{L0} rises. Therefore, the BB gain is kept constant with respect to a change in the local oscillation frequency f_{L0}. Further, fluctuation in the “RF gain” is also reduced.

As explained above, the radio receiving circuit according to this embodiment includes the low-noise amplifier 20 that amplifies a received radio frequency signal, the frequency conversion circuit 21 that multiplies together a signal from the low-noise amplifier 20 and a local oscillation signal and converts the multiplied signal into a baseband signal, the capacitors C1 and C2 interposed between the low-noise amplifier 20 and the frequency conversion circuit 21 and configured to be capable of changing capacitance, and the operational amplifier AP that amplifies the baseband signal. Therefore, because control targets are only the capacitors C1 and C2, it is possible to simplify a circuit configuration in addition to the effect of the radio receiving circuit according to the fourth embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A radio receiving circuit comprising:
a first amplifier that amplifies a received radio frequency signal;
a frequency conversion circuit that multiplies together a signal from the first amplifier and a local oscillation signal and converts the multiplied signal into a baseband signal;
a capacitor interposed between the first amplifier and the frequency conversion circuit; and
a second amplifier that includes a resistor and amplifies the baseband signal, wherein
gains in the frequency conversion circuit and the second amplifier are kept constant irrespective of a level of a local oscillation frequency input to the frequency conversion circuit.

2. The radio receiving circuit according to claim 1, wherein the resistor is controlled such that resistance thereof decreases as the local oscillation frequency input to the frequency conversion circuit rises.

3. The radio receiving circuit according to claim 2, further comprising a control unit that controls the resistor such that the resistance decreases as the local oscillation frequency rises.

4. The radio receiving circuit according to claim 1, wherein the capacitor is controlled such that capacitance decreases as the local oscillation frequency input to the frequency conversion circuit rises.

5. The radio receiving circuit according to claim 5, further comprising a control unit that controls the capacitor such that the capacitance decreases as the local oscillation frequency rises.

6. A radio receiving circuit comprising:
a first amplifier that amplifies a received radio frequency signal;
a frequency conversion circuit that multiplies together a signal from the first amplifier and a local oscillation signal and converts the multiplied signal into a baseband signal;
a capacitor interposed between the first amplifier and the frequency conversion circuit; and
a second amplifier that includes a resistor and amplifies the baseband signal; and
a resistor interposed between the frequency conversion circuit and the second amplifier and configured to be capable of changing resistance, wherein
gains in the frequency conversion circuit and the second amplifier are kept constant irrespective of a level of a local oscillation frequency input to the frequency conversion circuit.

7. The radio receiving circuit according to claim 6, wherein the resistor is controlled such that resistance thereof increases as the local oscillation frequency input to the frequency conversion circuit rises.

8. The radio receiving circuit according to claim 7, further comprising a control unit that controls the resistor such that the resistance increases as the local oscillation frequency rises.

9. A radio receiving circuit comprising:
a first amplifier that amplifies a received radio frequency signal;
a frequency conversion circuit that multiplies together a signal from the first amplifier and a local oscillation signal and converts the multiplied signal into a baseband signal;
a first capacitor interposed between the first amplifier and the frequency conversion circuit; and
a second amplifier that includes a resistor and a second capacitor and amplifies the baseband signal, wherein
gains in the frequency conversion circuit and the second amplifier are kept constant irrespective of a level of a local oscillation frequency input to the frequency conversion circuit.

10. The radio receiving circuit according to claim 9, wherein
the resistor is controlled such that resistance thereof decreases as the local oscillation frequency input to the frequency conversion circuit rises, and
the second capacitor is controlled such that capacitance thereof increases as the resistance decreases.

11. The radio receiving circuit according to claim 10, wherein the second amplifier is configured such that a time constant of the resistor and the second capacitor is made constant.

12. The radio receiving circuit according to claim 11, further comprising a control unit that controls the resistor such that the resistance decreases as the local oscillation frequency rises and increases the capacitance of the second capacitor such that the time constant is made constant as the resistance decreases.

13. The radio receiving circuit according to claim 9, wherein the first capacitor is controlled such that capacitance thereof decreases as the local oscillation frequency input to the frequency conversion circuit rises.

14. The radio receiving circuit according to claim 13, further comprising a control unit that controls the first capacitor such that the capacitance decreases as the local oscillation frequency rises.
